(19) United States
(12) Patent Application Publication
(10) Pub. No.: US 2012/0270406 A1
(43) Pub. Date: Oct. 25, 2012

(54) CLEANING METHOD OF PLASMA PROCESSING APPARATUS AND PLASMA PROCESSING METHOD

(75) Inventors: Shigeru Tahara, Yamanashi (JP); Eiichi Nishimura, Kurokawa (JP)

(73) Assignee: TOKYO ELECTRON LIMITED, Tokyo (JP)

(21) Appl. No.: 13/446,006

(22) Filed: Apr. 13, 2012

Related U.S. Application Data
(60) Provisional application No. 61/479,624, filed on Apr. 27, 2011.

(30) Foreign Application Priority Data
Apr. 13, 2011 (JP) 2011-089348

(51) Int. Cl. B08B 7/00; H01L 21/3065

(52) U.S. Cl. 438/710; 134/1.2; 257/E21.218

(57) ABSTRACT

A plasma processing apparatus in which a cleaning method is performed includes a plasma generating chamber, having a silicon-containing member, for generating therein plasma by exciting a processing gas; a plasma processing chamber communicating with the plasma generating chamber via a partition member; and a high frequency antenna, having a planar shape, provided at an outside of a dielectric window of the plasma generating chamber. The cleaning method includes exciting a hydrogen-containing processing gas into plasma in the plasma generating chamber, introducing hydrogen radicals in the plasma into the plasma processing chamber through the partition member, performing a plasma process on a processing target substrate by allowing the hydrogen radicals to act on the processing target substrate, unloading the processing target substrate, and removing silicon-based deposits generated in the plasma generating chamber by introducing a tetrafluoride (tetrafluoromethane) gas into the plasma generating chamber.

### CROSS-REFERENCE TO RELATED APPLICATION

This application claims the benefit of Japanese Patent Application No. 2011-089348 filed on Apr. 13, 2011 and U.S. Provisional Application Ser. No. 61/479,624 filed on Apr. 27, 2011, the entire disclosures of which are incorporated herein by reference.

### FIELD OF THE INVENTION

The present disclosure relates to a cleaning method of a plasma processing apparatus and also relates to a plasma processing method.

### BACKGROUND OF THE INVENTION

Conventionally, in the field of manufacture of semiconductor devices, there is known a plasma processing apparatus that is configured to perform various processes such as a film forming process or an etching process on a substrate such as a semiconductor wafer.

With regard to such a plasma processing apparatus, there is also known a technique for asking a resist or etching a film of a low dielectric constant by generating plasma of a hydrogen gas and acting hydrogen radicals in the plasma of the hydrogen gas on a processing target substrate. When using the plasma of the hydrogen gas, if a capacitively coupled plasma processing apparatus of, e.g., a parallel plate type is used, an electrode therein would be largely damaged by the hydrogen plasma. For this reason, an inductively coupled plasma processing apparatus configured to generate inductively coupled plasma (ICP) has been generally used.

One example of such an inductively coupled plasma processing apparatus is disclosed in Patent Document 1. In this plasma processing apparatus, a high frequency coil having a coil spring shape is provided at a sidewall of a cylindrical plasma generating chamber. This plasma generating chamber and a plasma processing chamber for accommodating therein a processing target substrate such as a semiconductor wafer are partitioned by a multiple number of shield plates (partition members) having through holes. With this configuration, only the radicals in plasma are selectively allowed to act on the substrate (see, for example, Patent Document 1).

In the plasma processing apparatus having the aforementioned configuration in which the cylindrical plasma generating chamber having the high frequency coil at the sidewall thereof and the plasma processing chamber are partitioned by the shield plates, the plasma generating chamber has typically a vertically elongated shape because the high frequency coil is provided at the sidewall thereof. If only the radicals in the plasma generated in the vertically elongated plasma generating chamber are moved so as to act on the processing target substrate, a moving distance of the radicals becomes long. Accordingly, it may be difficult for the radicals to act on the processing target substrate efficiently and, thus, the process may not be performed efficiently. Thus, in order to efficiently perform a process by hydrogen radicals, it is desirable to use a plasma processing apparatus having a configuration in which a dielectric window is provided at a ceiling of a processing chamber and a high frequency antenna having a planar shape is provided on the dielectric window.

Further, when cleaning an ashing apparatus by using oxygen plasma, there is known a cleaning method in which deposits generated in a plasma processing chamber, such as carbon components and titanium components are dry-cleaned by plasma of carbon tetrafluoride (tetrafluoromethane) so as to prevent a decrease in an ashing rate. Here, the carbon components are caused by a photoresist and the titanium components are caused by a titanium nitride film or a titanium film (as a barrier metal layer) formed on a semiconductor wafer (see, for example, Patent Document 2).
Patent Document 1: Japanese Patent Laid-open Publication No. 2009-016453
Patent Document 2: Japanese Patent Laid-open Publication No. H11-145115

In the aforementioned plasma processing method using the hydrogen plasma, a silicon-containing member may be used as a member for forming the plasma generating chamber. For example, the dielectric window or the partition member may be made of quartz or the like. In such a case, hydrogen ions accelerated by a plasma potential collide with the silicon-containing member. Accordingly, the silicon-containing member is sputtered, and sputtered particles are deposited at a portion of the plasma processing chamber where a plasma density is low. The deposits may be peeled off as particles by a thermal stress, and the particles may be attached to the processing target substrate within the plasma processing chamber.

### BRIEF SUMMARY OF THE INVENTION

In view of the foregoing problem, illustrative embodiments provide a plasma processing method and a cleaning method of a plasma processing apparatus, capable of preventing particles generated from a silicon-containing member for forming a plasma generating chamber from adhering to a processing target substrate.

In accordance with one aspect of an illustrative embodiment, there is provided a cleaning method of a plasma processing apparatus that includes a plasma generating chamber, having a silicon-containing member, for generating therein plasma by exciting a processing gas; a plasma processing chamber communicating with the plasma generating chamber via a partition member having openings; and a high frequency antenna, having a planar shape, provided at an outside of a plate-shaped dielectric window arranged at a ceiling of the plasma generating chamber. The cleaning method includes exciting a hydrogen-containing processing gas into plasma in the plasma generating chamber, introducing hydrogen radicals in the plasma into the plasma processing chamber through the partition member, performing a plasma process on a processing target substrate by allowing the hydrogen radicals to act on the processing target substrate, and unloading the processing target substrate from the plasma processing chamber; and removing silicon-based deposits generated in the plasma generating chamber by introducing a tetrafluoride (tetrafluoromethane) gas into the plasma generating chamber.

In accordance with another aspect of the illustrative embodiment, there is provided a plasma processing method performed in a plasma processing apparatus that includes a plasma generating chamber, having a silicon-containing member, for generating therein plasma by exciting a processing gas; a plasma processing chamber communicating with the plasma generating chamber via a partition member having openings; and a high frequency antenna, having a planar shape, provided at an outside of a plate-shaped dielectric window arranged at a ceiling of the plasma generating chamber. The plasma processing method includes exciting a hydrogen-containing processing gas into plasma in the plasma generating chamber, introducing hydrogen radicals in the plasma into the plasma processing chamber through the partition member, performing a plasma process on a processing target substrate by allowing the hydrogen radicals to act on the processing target substrate; unloading the processing target substrate on which the plasma process is performed from the plasma processing chamber; and after unloading the processing target substrate, removing silicon-based deposits generated in the plasma generating chamber by introducing a tetrafluoride (tetrafluoromethane) gas into the plasma generating chamber.

In accordance with the illustrative embodiment, it is possible to provide the plasma processing method and the cleaning method of the plasma processing apparatus, capable of preventing particles generated from the silicon-containing member of the plasma generating chamber from adhering to the processing target substrate.

### BRIEF DESCRIPTION OF THE DRAWINGS

Non-limiting and non-exhaustive embodiments will be described in conjunction with the accompanying drawings. Understanding that these drawings depict only several embodiments in accordance with the disclosure and are, therefore, not to be intended to limit its scope, the disclosure will be described with specificity and detail through use of the accompanying drawings, in which:

FIG. 1 is a schematic cross-sectional configuration view of a plasma processing apparatus in accordance with an illustrative embodiment;

FIG. 2 is a schematic configuration view of a high frequency antenna of the plasma processing apparatus of FIG. 1;

FIG. 3 is a diagram showing a relationship between a voltage and a current in the high frequency antenna of FIG. 2;

FIG. 4 is a graph showing a result of investigating a thickness variation of a thermal oxide film of a semiconductor wafer arranged on a dielectric window of the plasma processing apparatus of FIG. 1;

FIG. 5 is a graph showing a result of investigating a thickness variation of a thermal oxide film of a semiconductor wafer arranged on the dielectric window and a partition member of the plasma processing apparatus of FIG. 1;

FIG. 6 is a graph showing a result of investigating a thickness of a thermal oxide film of a semiconductor wafer arranged on the partition member of the plasma processing apparatus of FIG. 1; and

FIG. 7 is a flow chart for describing a process in accordance with the illustrative embodiment.

### DETAILED DESCRIPTION OF THE INVENTION

Hereinafter, illustrative embodiments will be described in detail with reference to the accompanying drawings.

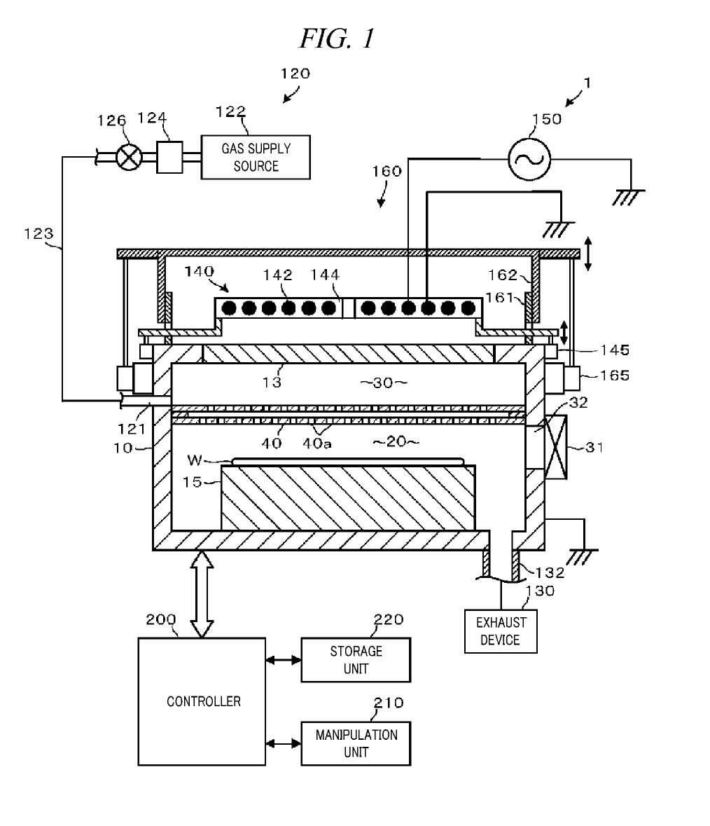

FIG. 1 schematically illustrates a configuration of a plasma processing apparatus 1 in accordance with an illustrative embodiment. The configuration of the plasma processing apparatus 1 will be first explained. The plasma processing apparatus 1 includes a processing chamber 10. The processing chamber 10 has a surface made of, but not limited to, an anodically oxidized aluminum and has a substantially cylindrical shape. A mounting table 15 for mounting thereon a processing target substrate such as a semiconductor wafer W is provided at a bottom portion within the processing chamber 10. A non-illustrated electrostatic chuck or the like for attracting and holding the processing target substrate is provided on a substrate mounting surface of the mounting table 15.

A dielectric window 13 made of quartz as a silicon-containing member is provided at a ceiling of the processing chamber 10 so as to face the mounting table 15. The dielectric window 13 has a circular plate shape and airtightly seals a circular opening formed at the ceiling of the chamber 10.

A partition member 40 made of quartz as a silicon-containing member is provided within the processing chamber 10 so as to partition the processing chamber 10 into a plasma processing chamber 20 below the partition member and a plasma generating chamber 30 above the partition member. The mounting table 15 is accommodated in the plasma processing chamber 20 and the partition member 40 has a multiple number of openings 40a.

The plasma etching apparatus 1 also includes a gas supply unit 120 for supplying a processing gas containing a hydrogen gas into the plasma generating chamber 30 of the processing chamber 10. A gas inlet port 121 is formed at a sidewall of the processing chamber 10, and a gas supply source 122 is connected to the gas inlet port 121 via a gas supply line 123. A mass flow controller 124 for controlling a flow rate of the processing gas and an opening/closing valve 126 are provided at a portion of the gas supply line 123. The processing gas from the gas supply source 122 is supplied into the plasma generating chamber 30 of the processing chamber 10 through the gas inlet port 121 while its flow rate is controlled by the mass flow controller 124.

In FIG. 1, for the simplicity of illustration, the gas supply unit 120 is depicted as a single system that supplies only a single kind of gas. However, the gas supply unit 120 may not only be configured to supply a processing gas of a single kind but may be configured to supply plural kinds of gases as processing gases. Further, the gas supply unit 120 may have a configuration of supplying a gas from a ceiling portion of the processing chamber 10 without being limited to the aforementioned configuration of supplying a gas from the sidewall of the processing chamber 10. In such a configuration, a gas inlet port may be provided at, e.g., a central portion of, e.g., the dielectric window 13, and the gas may be supplied through this gas inlet port.

An exhaust device 130 for evacuating the inside of the processing chamber 10 is connected to a bottom portion of the processing chamber 10 via an exhaust line 132. The exhaust device 130 includes, e.g., a vacuum pump and is capable of depressurizing the inside of the processing chamber 10 to a certain pressure level. A wafer loading/unloading port 32 is formed through a sidewall portion of the processing chamber 10. A gate valve 31 for opening and hermetically closing the wafer loading/unloading port 32 is provided at the wafer loading/unloading port 32.

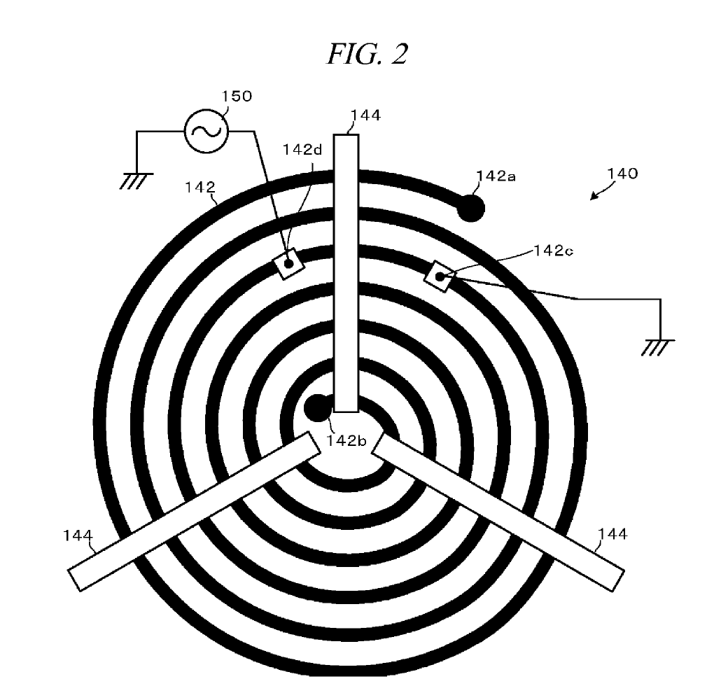

A high frequency antenna 140 having a planar shape is provided at an outside of the ceiling of the processing chamber 10 so as to face an exterior surface (top surface) of the dielectric window 13. A substantially barrel-shaped (in the present illustrative embodiment, cylindrical) shield member 160 is provided so as to cover the high frequency antenna 140. The high frequency antenna 140, as shown in FIG. 2, includes an antenna element 142 and a multiple number of, e.g., three supporting members 144 for supporting the antenna element 142. The antenna element 142 has a spiral coil shape and is made of a conductor such as, but not limited to, copper, aluminum or stainless steel. Each supporting member 144 has a rod shape, and the three supporting members 144 are radially elongated outward from a central portion toward the periphery of the antenna element 142.

The antenna element 142 is connected with a high frequency power supply 150. A high frequency power of a certain frequency (e.g., about 26.70 MHz) is applied to the antenna element 142 from the high frequency power supply 150 at a certain power level, so that an inductive magnetic field is formed within the plasma generating chamber 30 of the processing chamber 10. As a result, the processing gas including the hydrogen gas introduced in the plasma generating chamber 30 is excited into plasma. Ions in the plasma generated in the plasma generating chamber 30 are blocked by the partition member 40 and cannot reach the plasma processing chamber 20. Only the hydrogen radicals in the plasma reach the plasma processing chamber 20, and the semiconductor wafer W is processed by the hydrogen radicals.

The frequency of the high frequency power outputted from the high frequency power supply 150 may not be limited to, e.g., about 26.70 MHz but may be, e.g., about 13.56 MHz or about 60 MHz. Here, according to the frequency of the high frequency power outputted from the high frequency power supply 150, an electrical length of the antenna element 142 needs to be adjusted.

The shield member 160 includes a substantially cylindrical lower shield member 161 fixed at the ceiling portion of the processing chamber 10; and an upper shield member 162 slidably provided at an outer surface of the lower shield member 161. The upper shield member 162 has a substantially cylindrical shape having a closed top and an open bottom. The upper shield member 162 is configured to be slid up and down by an actuator 165 provided at the sidewall of the processing chamber 10. Further, the height of the high frequency antenna 140 is also adjustable by an actuator 145.

The plasma processing apparatus 1 includes a controller (overall control device) 200, and each component of the plasma processing apparatus 1 is controlled by the controller 200. The controller 200 is connected with a manipulation unit 210 including a keyboard through which an operator inputs commands to manage the plasma processing apparatus 1 or a display that visually displays operational status of the plasma processing apparatus 1.

Further, the controller 200 is also connected with a storage unit 220 that stores therein: programs for implementing various processes performed in the plasma processing apparatus 1 under the control of the controller 200; and recipes necessary for executing the programs.

To elaborate, the storage unit 220 stores not only a multiple number of recipes for implementing various processes of the semiconductor wafer W but also recipes for performing a necessary process such as cleaning of the inside of the processing chamber 10. These recipes may be stored in a hard disk or a semiconductor memory. Further, these recipes may be also set in a certain area of the storage unit 220 while stored in a storage medium such as a CD-ROM or a DVD.

The controller 200 reads out a desired recipe from the storage unit 220 in response to, e.g., an instruction from the manipulation unit 210 and controls each component of the plasma processing apparatus 1. As a result, a required process is performed in the plasma processing apparatus 1. The recipe can be edited by the manipulation unit 210.

Now, a detailed configuration of the high frequency antenna 140 will be explained. As shown in FIG. 2, in the high frequency antenna 140, both ends of the antenna element 142, i.e., an outer end 142a and an inner end 142b are free ends (in electrically floating states). A middle point of a length of the antenna element 142 in a winding direction or the vicinity thereof (hereinafter, simply referred to as a “middle point”) is set as a grounding point (ground) 142c. With this configuration, the high frequency antenna 140 is capable of generating a standing wave of a ½ wavelength.

That is, a length, a winding diameter, a winding pitch and a winding number of the antenna element 142 are set in order the antenna element 142 to resonate at about ½ the wavelength of a reference frequency, i.e., the frequency (e.g., about 26.70 MHz) supplied from the high frequency power supply 150 (i.e., resonate in a half-wave mode). By way of example, the antenna element 142 has an electrical length allowing it to resonate at about ½ the reference frequency. That is, the electrical length of the antenna element 142 is equivalent to about ½ the wavelength at the reference frequency of about 26.70 MHz. The antenna element 142 may have any shape, such as a pipe shape, a line shape or a plate shape.

A power supply point 142d for supplying the high frequency power from the high frequency power supply 150 may be set at a position at an inner side or an outer side than that of the grounding point 142c. By way of example, the power supply point 142d may be set at a position where impedance becomes about 50Ω. The power supply point may be variable. In such a case, the power supply point may be automatically varied by a motor or the like.

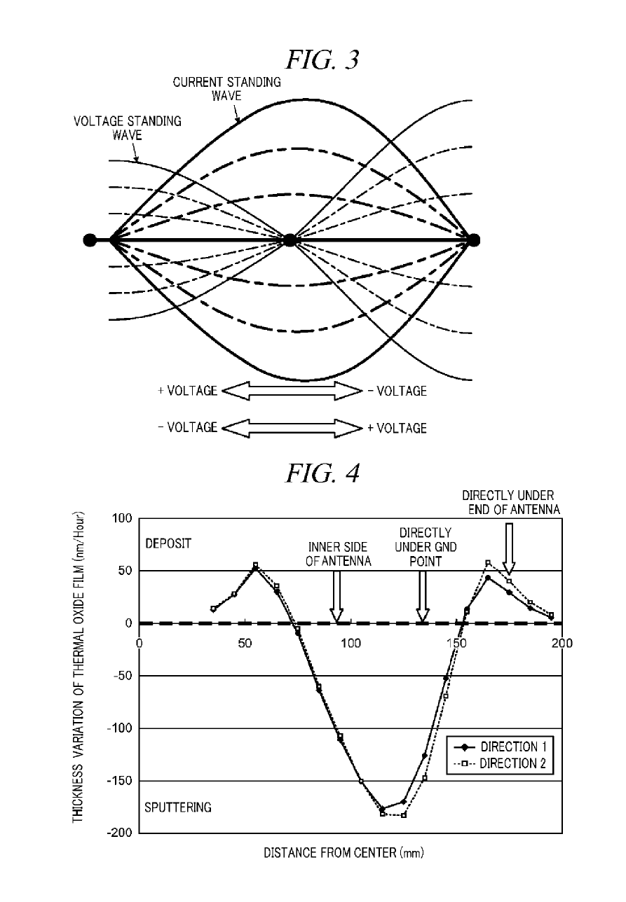

With this antenna element 142, if a high frequency power of a reference frequency (e.g., about 26.70 MHz) is applied to the high frequency antenna 140 and the antenna element 142 is resonated in a half-wave mode, at a certain moment, a voltage V applied to the antenna element 142 becomes to have a waveform in which the middle point (grounding point) of the antenna element 142 has a value of about zero; one end thereof has a positive peak; and the other end thereof has a negative peak, as shown in FIG. 3. Meanwhile, a phase of a current I applied to the antenna element 142 is deviated from that of the voltage by about 90 degrees. Thus, the current I has a waveform in which the middle point (grounding point) thereof has a maximum value and both ends have a value of about zero.

At this time, since instant capacities increase and decrease in inverse directions for each positive-negative cycle of the high frequency, the voltage V and the current I applied to the antenna element 142 become to have waveforms as depicted in FIG. 3. That is, for the voltage V, a standing wave in a half wave mode is generated, where positive and negative voltage components generated on the antenna element 142 are offset and an average voltage becomes very small. For the current I, on the other hand, a standing wave, where the middle point (grounding point) on the antenna element 142 has a peak value and only positive current value or only negative current value exists, is generated.

By these standing waves, a vertical magnetic field B having a maximum strength is generated near the center of the antenna element 142. Accordingly, a circular electric field centered in the vertical magnetic field B is generated in the plasma generating chamber 30 so that donut-shaped plasma is generated. At this time, since the average voltage applied to the antenna element 142 is very small, the degree of capacitive coupling is very weak. As a result, plasma having a low electric potential can be generated.

Here, if both the outer end 142a and the inner end 142b of the antenna element 142 are grounded and the high frequency power supply 150 is connected between the outer end 142a and the ground, the waveforms of the voltage V and the current I depicted in FIG. 3 are inverted. That is, if a high frequency power of a reference frequency (e.g., about 26.70 MHz) is applied to the high frequency antenna 140 and the antenna element 142 is resonated in a half-wave mode, at a certain moment, the voltage V applied to the antenna element 142 becomes to have a waveform in which the middle point (grounding point) thereof has a maximum value and both ends have a value of about zero. On the other hand, since the phase of the current I applied to the antenna element 142 is deviated from the phase of the voltage by about 90 degrees, the current I has a waveform in which the middle point (grounding point) of the antenna element 142 has a value of about zero; one end thereof has a positive peak; and the other end thereof has a negative peak.

In this way, if both ends of the antenna element 142 are grounded and the antenna element 142 is resonated in the half-wave mode, magnetic fields, in which magnetic field at an inner side of the antenna element 142 has an opposite direction at an outer side of the antenna element 142 with the grounding point as a boundary, are formed. By the magnetic fields of the opposite directions, two circular electric fields are formed adjacent to each other on a substantially same plane. Since the directions of the two circular electric fields are opposite to each other, the two electric fields may interference with each other. As a result, the generated plasma may become unstable.

In contrast, if the middle point of the antenna element 142 is set as the grounding point, only one circular electric field is formed in one direction, and there is generated no interfering electric field of the opposite direction. Thus, if the middle point of the antenna element 142 is set as the grounding point, stable plasma can be generated as compared to the case of setting both ends of the antenna elements 142 as the grounding points.

Further, if both ends of the antenna element 142 are grounded, a voltage component may remain on the antenna element 142 in a resonance state. Accordingly, a great amount of capacitively coupled components are generated in the plasma. On the other hand, if the middle point of the antenna element 142 is set as the grounding point, capacitively coupled components are difficult to be generated in the plasma since a voltage component on the antenna element 142 in the resonance state is very small, as stated above. Thus, in order to perform a plasma process with little damage, it may be advantageous to set the middle point of the antenna element 142 as the grounding point.

In accordance with the illustrative embodiment, in order to resonate the antenna element 142 in the half-wave mode, the electrical length of the antenna element 142 needs to be set to be accurately equivalent to about ½ the wavelength of the reference frequency (here, e.g., about 26.70 MHz). However, it is not easy to fabricate the antenna element 142 with the accurate physical length. Further, the resonance frequency of the antenna element 142 may be affected by a stray capacitance between the antenna element 142 and the shield member 160 as well as an intrinsic reactance of the antenna element 142. Thus, even if it is possible to fabricate the antenna element 142 with the accurate physical length, an error in a distance between the antenna element 142 and the shield member 160 may occur due to an installation error or the like. Accordingly, it may not be possible to obtain a resonance frequency as designed.

In order to solve this problem, in accordance with the present illustrative embodiment, there is employed a configuration in which the height of the shield member 160 is adjustable. Thus, the stray capacitance can be varied by adjusting the distance between the antenna element 142 and the shield member 160. With this configuration, the resonance frequency of the antenna element 142 can be adjusted. To elaborate, if the upper shield member 162 is lifted up by driving the actuator 165, the distance between the shield member 160 and the high frequency antenna 140 is increased. Accordingly, the stray capacitance C is decreased, and, thus, the resonance frequency can be adjusted so as to lengthen the electrical length of the antenna element 142.

On the contrary, if the upper shield member 162 is lifted down, the distance between the shield member 160 and the high frequency antenna 140 is decreased. Accordingly, the stray capacitance C is increased, and, thus, the resonance frequency can be adjusted so as to shorten the electrical length of the antenna element 142. As described above, in accordance with the present illustrative embodiment, by adjusting the height of the shield member 160, the stray capacitance C between the antenna element 142 and the shield member 160 can be varied. Thus, the resonance frequency of the antenna element 142 can be adjusted without changing the physical length of the antenna element 142.

Further, in accordance with the present illustrative embodiment, the height of the high frequency antenna 140 may also be adjustable. Accordingly, by adjusting the distance between the plasma and the antenna element 142, a plasma potential can be adjusted.

The heights of the high frequency antenna 140 and the shield member 160 are adjusted by driving the actuators 145 and 165 under the control of the controller 200, respectively. In this case, the height adjustment of the high frequency antenna 140 and the shield member 160 may be carried out by the manipulation of the operator through the manipulation unit 210 or by the automatic control of the controller 200.

By way of example, in the configuration for adjusting the height of the shield member 160 automatically, a high frequency power meter (e.g., a reflection wave power meter) may be provided at an output side of the high frequency power supply 150. Based on a high frequency power detected by the high frequency power meter, the actuator 165 may be controlled (so as to minimize a reflection wave power, for example), to adjust the height of the shield member 160. Accordingly, the resonance frequency of the antenna element 142 is automatically adjusted.

When performing a plasma process on a semiconductor wafer W by the plasma processing apparatus 1 having the above-described configuration, the gate valve 31 is opened, and the semiconductor wafer W is loaded into the plasma processing chamber 20 of the processing chamber 10 through the wafer loading/unloading port 32. Then, the semiconductor wafer W is mounted on the mounting table 15 and is attracted to and held on the electrostatic chuck.

Subsequently, the gate valve 31 is closed, and the inside of the processing chamber 10 is evacuated to a certain vacuum level by a non-illustration vacuum pump or the like of the exhaust device 130.

Thereafter, a processing gas including a hydrogen gas of a certain flow rate is supplied into the plasma generating chamber 30 of the processing chamber 10. By way of example, the processing gas may be a gas including a hydrogen gas and a rare gas (Ar, He, or the like) or a gas including a hydrogen gas and an oxygen gas. Then, after the pressure within the processing chamber 10 is controlled to have a certain pressure level, a high frequency power of a certain frequency is applied to the high frequency antenna 140 from the high frequency power supply 150. As a result, ICP plasma of the processing gas including the hydrogen gas is generated within the plasma generating chamber 30.

Ions in the ICP plasma have electrical charges and cannot reach the plasma processing chamber 20 by being blocked by the partition member 40. Meanwhile, hydrogen radicals in the ICP plasma are electrically neutral and can reach the inside of the plasma processing chamber 20 through the openings 40a of the partition member 40. As a result, the hydrogen radicals act on the semiconductor wafer W mounted on the mounting table 15. Accordingly, a plasma process such as an etching process or an asking process is performed on the semiconductor wafer W.

Here, in the plasma processing apparatus 1, the ICP plasma is generated by using the high frequency antenna 140 having the planar shape, and the plasma exists in a region relatively close to the semiconductor wafer W. Accordingly, it is allowable that the moving amount of the hydrogen radicals from the plasma to the semiconductor wafer W is small. Thus, the hydrogen radicals having short lifetime can act on the semiconductor wafer W efficiently.

Upon the completion of the plasma process, the application of the high frequency power and the supply of the processing gas are stopped, and the semiconductor wafer W is unloaded from the processing chamber 10 in the reverse sequence to that described above. After the semiconductor wafer W is unloaded from the processing chamber 10, a cleaning process may be performed, if necessary.

A graph of FIG. 4 shows a measurement result of a thickness variation of a thermal oxide film on a rectangular piece of semiconductor wafer while arranging the rectangular piece of semiconductor wafer having thereon the thermal oxide film on a vacuum-side surface of the dielectric window 13 in a diametric direction of the dielectric window 13 and generating plasma of a hydrogen-containing gas in the plasma generating chamber 30. A vertical axis of the graph of FIG. 4 represents a thickness variation (nm/Hour) of the thermal oxide film, and a horizontal axis represents a distance (mm) from the center toward a periphery of the processing chamber 10. Further, the direction 1 in FIG. 4 indicates a direction passing through directly under the outer end 142a and the grounding point (ground) 142c of the antenna element 142, and the direction 2 indicates a direction toward the gate valve.

Conditions for the plasma generation are as follows.

Processing gas: He/H₂: about 2400/about 100 sccm
Pressure: about 1995 Pa (about 1.5 Torr)
High frequency power: about 3000 W
Source current: about 23.0 A
Resonance frequency: about 26.70 MHz
Discharge time: about 30 seconds×120 times (total 1 hour) (cooling for about 5 minutes between discharges)

As can be seen from the graph of FIG. 4, at a middle region in the diametric direction (i.e., a position where a distance from the center ranges from about 75 mm to about 150 mm), the thickness variation of the thermal oxide film has minus values, which implies that the thermal oxide film is sputtered. Meanwhile, at an inner region and an outer region than the middle region, the thickness variation of the thermal oxide film has plus values, which implies that deposits are generated at those regions. The region where the thermal oxide film is sputtered is a portion where a plasma density is high, whereas the region where the deposits are generated is a portion where the plasma density is low. Further, there is found no significant difference between the direction 1 and the direction 2. This experiment shows the result for the thermal oxide film (SiO₂ film) formed on the piece of semiconductor wafer. Likewise, on the vacuum-side surface of the dielectric window 13 which is made of quartz as a silicon-containing member, a portion of the dielectric window 13 where the plasma density is high is sputtered, whereas sputtered particles are deposited at a portion of the dielectric window 13 where the plasma density is low. Further, in an actual plasma process using the hydrogen plasma, a gaseous mixture of a hydrogen gas and an oxygen gas or a gaseous mixture of a hydrogen gas and a rare gas (e.g., an Ar gas) may be used as a processing gas, besides a single hydrogen gas.

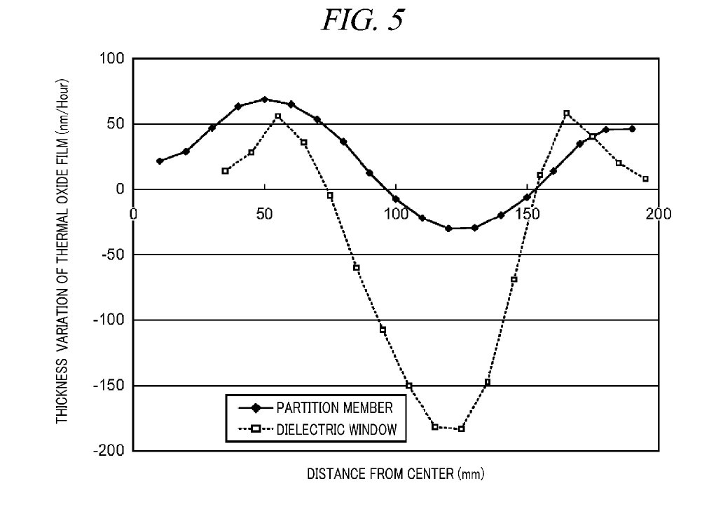

A graph of FIG. 5 shows a measurement result of a thickness variation of a thermal oxide film for each of rectangular pieces of semiconductor wafer arranged on a vacuum-side surface of the dielectric window 13 and a top surface of the partition member 40 in the direction 2. A vertical axis of the graph of FIG. 5 represents a thickness variation (nm/Hour) of the thermal oxide film, and a horizontal axis represents a distance (mm) from the center toward the periphery of the processing chamber 10.

As can be seen from the graph of FIG. 5, like the vacuum-side surface of the dielectric window 13, the top surface of the partition member 40 also has a region that is sputtered and a region where deposits are generated. As compared to the vacuum-side surface of the dielectric window 13, the region where the deposits are generated becomes larger, and the amount of the deposits becomes greater. This experiment also shows the result for the thermal oxide film (SiO₂ film) formed on the piece of semiconductor wafer. Likewise, on the top surface of the partition member 40 made of quartz as the silicon-containing member, a portion of the partition member 40 where the plasma density is high is sputtered, whereas sputtered particles are deposited at a portion of the partition member 40 where the plasma density is low.

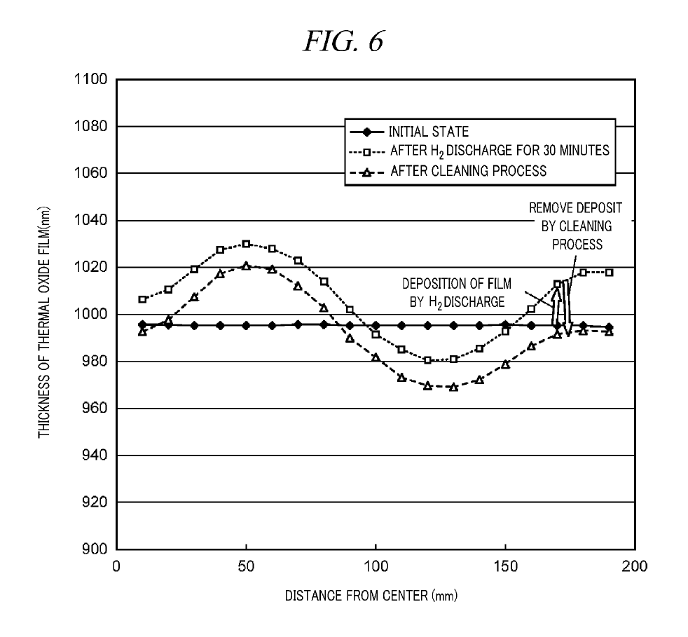

A graph of FIG. 6 shows a measurement result of a thickness of a thermal oxide film on the top surface of the partition member 40. A vertical axis of the graph represents a thickness (nm) of the thermal oxide film, and a horizontal axis represents a distance (mm) from the center toward the periphery of the processing chamber 10. On the graph of FIG. 6, rhombus-shaped plots indicate an initial thickness of the thermal oxide film. Square plots indicate a film thickness after a discharge by a hydrogen gas, as a simulation process for a plasma process on a semiconductor wafer by hydrogen plasma, is performed for about 30 minutes. Triangular plots indicate a film thickness after a cleaning process is performed.

The cleaning process is performed under the following conditions.

Processing gas: CF₄=about 200 sccm
Pressure: about 26.6 Pa (about 200 mTorr)
High frequency power: about 3000 W
Source current: about 23.0 A
Resonance frequency: about 26.70 MHz
Discharge time: about 30 seconds

As can be seen from the graph of FIG. 6, after the discharge by the hydrogen gas as the simulation process for the plasma process on the semiconductor wafer by hydrogen plasma, deposits are generated at a portion where a plasma density is low. Further, it is also proved that these deposits can be removed by performing the cleaning process under the above-specified conditions. In the example shown in FIG. 6, the cleaning process is performed only for about seconds for the plasma process performed for about 30 minutes. Thus, the deposits are not completely removed. However, if the cleaning process is performed for about 2 to about 3 minutes, the deposit may be completely removed.

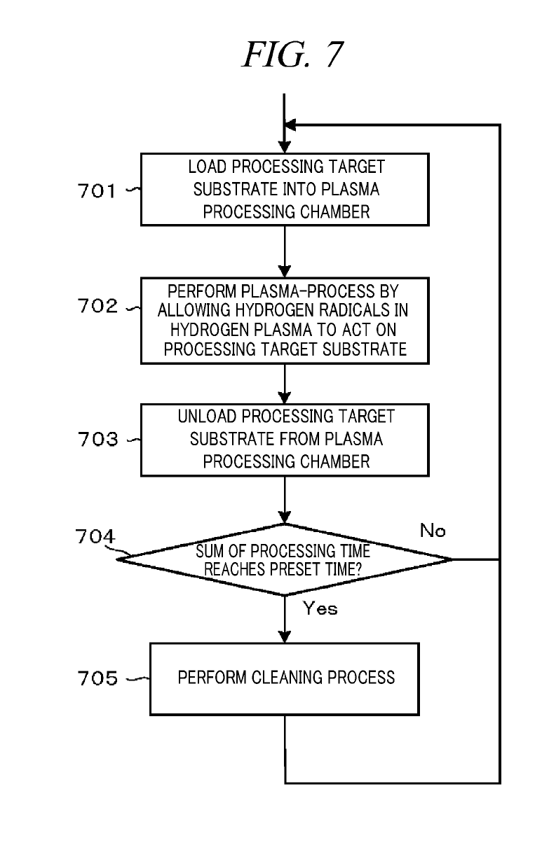

In an actual plasma process, in order to effectively prevent sputtered deposits from adhering to the semiconductor wafer, it may be desirable to perform the cleaning process before the amount of the deposits becomes greater. By way of example, after the plasma processes are performed on several sheets of wafers, it may be desirable to perform the aforementioned cleaning process whenever the sum of the processing time of each plasma process becomes a preset time, e.g., about 5 minutes to about 10 minutes. In such a case, desirably, the cleaning process may be performed while the semiconductor wafer is not loaded into the plasma processing chamber. For this reason, the plasma process on the semiconductor wafer by the hydrogen plasma is performed as shown in a flowchart of FIG. 7.

That is, a process 701 for loading a processing target substrate into the plasma processing chamber; a process 702 for performing the plasma process on the processing target substrate by allowing hydrogen radicals in the hydrogen plasma to act on the processing target substrate; and a process 703 for unloading the processing target substrate from the plasma processing chamber are repetitively performed. Through these processes, the plasma process is performed on a preset number of processing target substrates. At this time, after the completion of the process 703 for unloading the processing target substrate from the plasma processing chamber, it is determined in a process 704 whether the sum of the processing time of each plasma process reaches a preset time. If the sum of the processing time of each plasma process is found to reach the preset time, the cleaning process is performed in a process 705. Meanwhile, if the sum of the processing time of each plasma process is found not to reach the preset time, the process 701 for loading the next processing target substrate into the plasma processing chamber is performed, and the plasma process of the single-wafer type is continuously performed.

While the present illustrative embodiment has been described herein, it does not limit the present disclosure. It would be understood that various changes and modifications may be made.

What is claimed is:

1. A cleaning method of a plasma processing apparatus that includes a plasma generating chamber, having a silicon-containing member, for generating therein plasma by exciting a processing gas; a plasma processing chamber communicating with the plasma generating chamber via a partition member having openings; and a high frequency antenna, having a planar shape, provided at an outside of a plate-shaped dielectric window arranged at a ceiling of the plasma generating chamber, the cleaning method comprising:
exciting a hydrogen-containing processing gas into plasma in the plasma generating chamber, introducing hydrogen radicals in the plasma into the plasma processing chamber through the partition member, performing a plasma process on a processing target substrate by allowing the hydrogen radicals to act on the processing target substrate, and unloading the processing target substrate from the plasma processing chamber; and
removing silicon-based deposits generated in the plasma generating chamber by introducing a tetrafluoride (tetrafluoromethane) gas into the plasma generating chamber.

2. The cleaning method of claim 1, wherein the hydrogen-containing processing gas includes either an oxygen gas or a rare gas.

3. The cleaning method of claim 2, wherein the rare gas is an argon gas.

4. The cleaning method of claim 1, wherein the dielectric window contains silicon.

5. The cleaning method of claim 1, wherein the partition member contains silicon.

6. A plasma processing method performed in a plasma processing apparatus that includes a plasma generating chamber, having a silicon-containing member, for generating therein plasma by exciting a processing gas; a plasma processing chamber communicating with the plasma generating chamber via a partition member having openings; and a high frequency antenna, having a planar shape, provided at an outside of a plate-shaped dielectric window arranged at a ceiling of the plasma generating chamber, the plasma processing method comprising:
exciting a hydrogen-containing processing gas into plasma in the plasma generating chamber, introducing hydrogen radicals in the plasma into the plasma processing chamber through the partition member, performing a plasma process on a processing target substrate by allowing the hydrogen radicals to act on the processing target substrate;
unloading the processing target substrate on which the plasma process is performed from the plasma processing chamber; and
after unloading the processing target substrate, removing silicon-based deposits generated in the plasma generating chamber by introducing a tetrafluoride (tetrafluoromethane) gas into the plasma generating chamber.

7. The plasma processing method of claim 6, wherein the hydrogen-containing processing gas includes either an oxygen gas or a rare gas.

8. The plasma processing method of claim 7, wherein the rare gas is an argon gas.

9. The plasma processing method of claim 6, wherein the dielectric window contains silicon.

10. The plasma processing method of claim 6, wherein the partition member contains silicon.
